(19) United States
(12) Patent Application Publication
(10) Pub. No.: US 2013/0074773 A1
(43) Pub. Date: Mar. 28, 2013

(54) HEATING SYSTEMS FOR THIN FILM FORMATION

(71) Applicant: Heng LIU, Sunnyvale, CA (US)

(72) Inventor: Heng LIU, Sunnyvale, CA (US)

(73) Assignee: Pinecone Material Inc, Taipei City (TW)

(21) Appl. No.: 13/247,889

(22) Filed: Sep. 28, 2011

(51) Int. Cl. C23C 16/46

(52) U.S. Cl. 118/725

(57) ABSTRACT

System for forming one or more layers of one or more materials on one or more substrates. The system includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates. Each of the one or more substrates includes a substrate surface facing the heating device and associated with a bow height, and the heating device is located away from the substrate surface by a distance. For each of the one or more substrates, the distance is at least twenty times as large as the bow height.

### 1. BACKGROUND OF THE INVENTION

The present invention is directed to systems of material fabrication. More particularly, the invention provides a heating system for forming epitaxial layers of semiconductor materials. Merely by way of example, the invention has been applied to metal-organic chemical vapor deposition. But it would be recognized that the invention has a much broader range of applicability.

Thin film deposition has been widely used for surface processing of various objects, such as jewelry, dishware, tools, molds, and/or semiconductor devices. Often, on surfaces of metals, alloys, ceramics, and/or semiconductors, thin films of homogeneous or heterogeneous compositions are formed in order to improve wear resistance, heat resistance, and/or corrosion resistance. The techniques of thin film deposition usually are classified into at least two categories—physical vapor deposition (PVD) and chemical vapor deposition (CVD).

Depending on deposition techniques and process parameters, the deposited thin films may have a crystalline, polycrystalline or amorphous structure. The crystalline thin films often are used as epitaxial layers, which are important for fabrication of integrated circuits. For example, the epitaxial layers are made of semiconductor and doped during formation, resulting in accurate dopant profiles without being contaminated by oxygen and/or carbon impurities.

One type of chemical vapor deposition (CVD) is called metal-organic chemical vapor deposition (MOCVD). For MOCVD, one or more carrier gases can be used to carry one or more gas-phase reagents and/or precursors into a reaction chamber that contains one or more substrates (e.g., one or more wafers). The backside of the substrates usually is heated through radio-frequency induction or by a resistor, in order to raise the temperature of the substrates and their ambient temperature. At the elevated temperatures, one or more chemical reactions can occur, converting the one or more reagents and/or precursors (e.g., in gas phase) into one or more solid products that are deposited onto the surface of the substrates.

FIG. 1 is a simplified conventional diagram showing bowing of a substrate. The substrate 110 (e.g., a wafer) is located on a substrate holder 120. As shown, the substrate 110 has a bow with a height as indicated by the vertical distance of ΔZ. Often, the substrate bowing is caused by stress that results from lattice mismatch.

FIGS. 2(A) and (B) are simplified conventional diagrams showing a resistance heater for heating the substrate 110 through the substrate holder 120. The resistance heater 200 includes heating resistors 210, a reflection plate 220, a graphite base plate 230, and a quartz cover 240. The heating resistors 210 include one or more resistors 212, one or more resistors 214, and one or more resistors 216. The temperature of the resistors 212, the temperature of the resistors 214, and the temperature of the resistors 216 often can be adjusted separately. Usually, the heating resistors 210 are used to heat up the graphite base plate 230 by thermal radiation. Because the graphite base plate 230 often possesses high thermal conductivity, the graphite base plate 230 can achieve uniform temperature rather quickly, and is used to heat up the substrate 110 through the substrate holder 120.

When the substrate 110 is heated through the substrate holder 120, the bowing of the substrate 110 can lead to temperature non-uniformity, causing inhomogeneity of one or more solid products that are deposited onto the substrate by MOCVD. For example, the temperature non-uniformity can adversely affect uniformity of material quality, material composition, and/or film stress.

Hence it is highly desirable to improve techniques for heating the substrate.

### 2. BRIEF SUMMARY OF THE INVENTION

The present invention is directed to systems of material fabrication. More particularly, the invention provides a heating system for forming epitaxial layers of semiconductor materials. Merely by way of example, the invention has been applied to metal-organic chemical vapor deposition. But it would be recognized that the invention has a much broader range of applicability.

According to one embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates directly without through the susceptor component and the substrate holder. The heating device is further configured to provide a first temperature on the one or more substrates only if the one or more substrates rotate around at least the susceptor axis, and the first temperature is constant along the radial direction from the susceptor axis.

According to another embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates directly without through the susceptor component and the substrate holder. The heating device is further configured to provide a first temperature on the one or more substrates only if the one or more substrates rotate around at least the susceptor axis, and the first temperature is constant along a first radial direction from the susceptor axis. The heating device includes a first plurality of heating resistors and a second plurality of heating resistors. Each of the first plurality of heating resistors is located along a second radial direction from the susceptor axis, and each of the second plurality of heating resistors is conductively connected to at least two heating resistors selected from the first plurality of heating resistors.

According to yet another embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates. Each of the one or more substrates includes a substrate surface facing the heating device and associated with a bow height, and the heating device is located away from the substrate surface by a distance. For each of the one or more substrates, the distance is at least twenty times as large as the bow height.

Depending upon embodiment, one or more of these benefits may be achieved. These benefits and various additional objects, features and advantages of the present invention can be fully appreciated with reference to the detailed description and accompanying drawings that follow.

### 3. BRIEF DESCRIPTION OF THE DRAWINGS

FIG. 1 is a simplified conventional diagram showing bowing of a substrate.

FIGS. 2(A) and (B) are simplified conventional diagrams showing a resistance heater for heating the substrate through the substrate holder.

FIGS. 3(A) and (B) are simplified diagrams showing a reaction system that includes a rotation system for forming one or more materials on one or more substrates according to one embodiment.

FIG. 4 is a simplified diagram showing indirect heating of a substrate by a heating device as part of the reaction system according to one embodiment.

FIG. 5 is a simplified diagram showing direct heating of a substrate by a heating device as part of the reaction system according to another embodiment.

FIG. 6 is a simplified diagram showing the heating device used for direct heating of the substrate as shown in FIG. 5 according to one embodiment.

FIG. 7 is a simplified diagram showing temperature distribution on the substrate that is directly heated by the heating device as shown in FIG. 6 according to one embodiment.

FIGS. 8(A) and (B) are simplified diagrams showing temperature distributions on the substrate that is directly heated by the heating device as shown in FIG. 5 according to one embodiment of the present invention.

FIG. 9 is a simplified diagram showing temperature distribution on the substrate that is directly heated by the heating device as shown in FIG. 5 according to another embodiment of the present invention.

FIGS. 10(A) and (B) are simplified diagrams showing a resistance heating device as the heating device for directly heating the substrate as shown in FIG. 5 according to yet another embodiment of the present invention.

FIGS. 11(A) and (B) are simplified diagrams showing the substrate that can be directly heated by the radio-frequency (RF) heating device as the heating device as shown in FIG. 5 according to certain embodiments of the present invention.

FIGS. 12 (A) and (B) are simplified diagrams showing effects of bowing of a substrate on substrate temperature according to certain embodiments.

FIGS. 13 (A) and (B) are simplified diagrams showing effects of bowing of a substrate on substrate temperature according to some embodiments.

FIG. 14 is a simplified diagram showing distant heating of a substrate by a heating device through a susceptor and a corresponding substrate holder as part of the reaction system according to yet another embodiment of the present invention.

### 4. DETAILED DESCRIPTION OF THE INVENTION

The present invention is directed to systems of material fabrication. More particularly, the invention provides a heating system for forming epitaxial layers of semiconductor materials. Merely by way of example, the invention has been applied to metal-organic chemical vapor deposition. But it would be recognized that the invention has a much broader range of applicability.

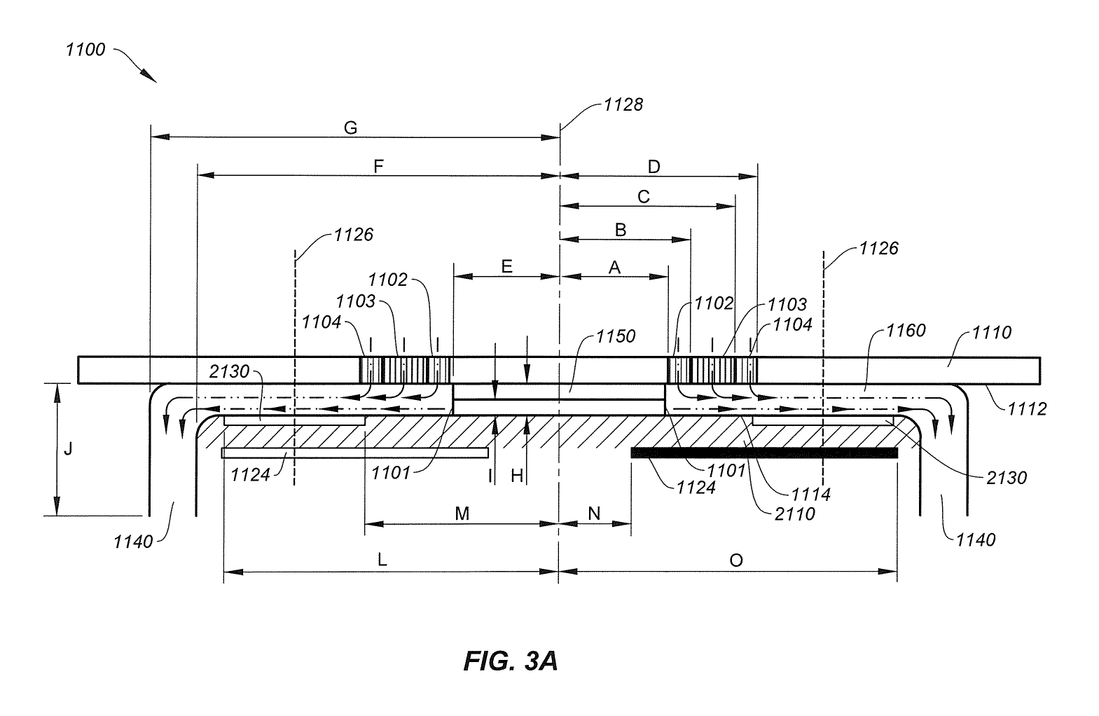

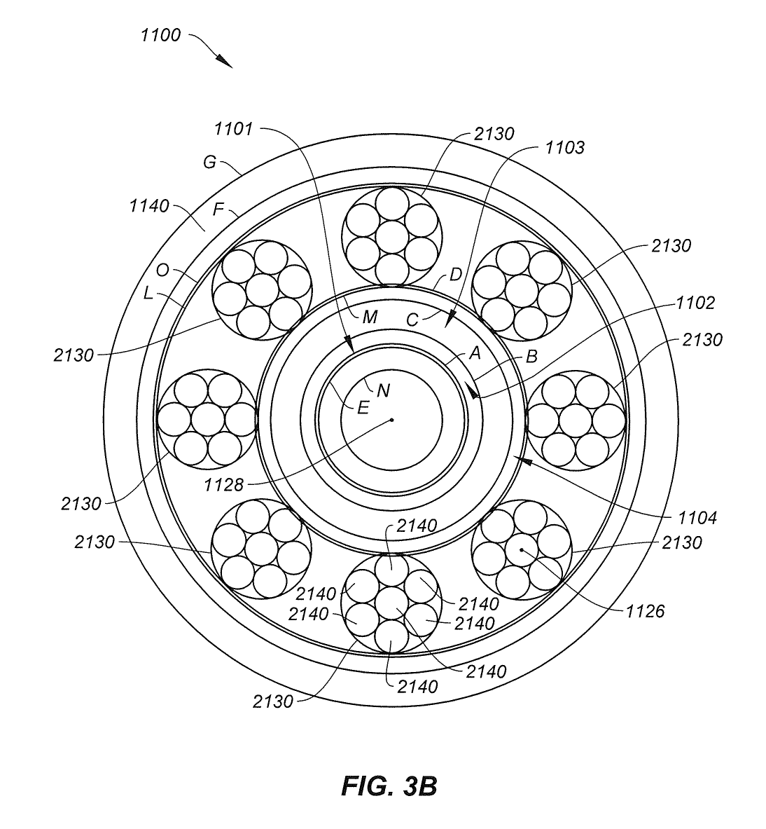

FIGS. 3(A) and (B) are simplified diagrams showing a reaction system that includes a rotation system for forming one or more materials on one or more substrates according to one embodiment. For example, FIG. 3(A) shows a side view of the reaction system 1100, and FIG. 3(B) shows a planar view of the reaction system 1100. In another example, the reaction system 1100 includes a showerhead component 1110, the susceptor 2110, inlets 1101, 1102, 1103 and 1104, one or more substrate holders 2130, one or more heating devices 1124, an outlet 1140, and a central component 1150. In yet another example, the central component 1150, the showerhead component 1110, the susceptor 2110, and the one or more substrate holders 2130 (e.g., located on the susceptor 2110) form a reaction chamber 1160 with the inlets 1101, 1102, 1103 and 1104 and the outlet 1140. In yet another example, the one or more substrate holders 2130 each are used to carry one or more substrates 2140 (e.g., one or more wafers).

Although the above has been shown using a selected group of components for the system 1100, there can be many alternatives, modifications, and variations. For example, some of the components may be expanded and/or combined. Other components may be inserted to those noted above. Depending upon the embodiment, the arrangement of components may be interchanged with others replaced.

According to one embodiment, the inlet 1101 is formed within the central component 1150 and configured to provide one or more gases in a direction that is substantially parallel to a surface 1112 of the showerhead component 1110. For example, the one or more gases flow (e.g., flow up) into the reaction chamber 1160 near the center of the reaction chamber 1160 and then flow through the inlet 1101 outward radially, away from the center of the reaction chamber 1160. According to another embodiment, the inlets 1102, 1103 and 1104 are formed within the showerhead component 1110 and configured to provide one or more gases in a direction that is substantially perpendicular to the surface 1112.

For example, various kinds of gases are provided through the inlets 1101, 1102, 1103 and 1104 as shown in Table 1.

TABLE 1

| Inlets | 1101 | 1102 | 1103 | 1104 |
|---|---|---|---|---|
| Gases | NH₃ | N₂, H₂, and/or | N₂, H₂, and/or | N₂, H₂, and/or |
| | | TMG | NH₃ | TMG |

In one embodiment, the susceptor 2110 is configured to rotate around a susceptor axis 1128 (e.g., a central axis), and each of the one or more substrate holders 2130 is configured to rotate around a corresponding holder axis 1126. In another embodiment, the one or more substrate holders 2130 can rotate, with the susceptor 2110, around the susceptor axis 1128, and also rotate around their corresponding holder axes 1126. For example, the one or more substrates 2140 on the same substrate holder 2130 can rotate around the same holder axis 1126.

According to one embodiment, the inlets 1101, 1102, 1103 and 1104, and the outlet 1140 each have a circular configuration around the susceptor axis 1128. According to another embodiment, the one or more substrate holders 2130 (e.g., eight substrate holders 2130) are arranged around the susceptor axis 1128. For example, each of the one or more substrate holders 2130 can carry several substrates 2140 (e.g., seven substrates 2140).

As shown in FIGS. 3(A) and (B), symbols A, B, C, D, E, F, G, H, I, J, L, M, N, and O represent various dimensions of the reaction system 1100 according to some embodiments. In one embodiment,
(1) A represents the distance between the susceptor axis 1128 and the inner edge of the inlet 1102;
(2) B represents the distance between the susceptor axis 1128 and the inner edge of the inlet 1103;
(3) C represents the distance between the susceptor axis 1128 and the inner edge of the inlet 1104;
(4) D represents the distance between the susceptor axis 1128 and the outer edge of the inlet 1104;
(5) E represents the distance between the susceptor axis 1128 and the inlet 1101;
(6) F represents the distance between the susceptor axis 1128 and the inner edge of the outlet 1140;
(7) G represents the distance between the susceptor axis 1128 and the outer edge of the outlet 1140;
(8) H represents the distance between the surface 1112 of the showerhead component 1110 and a surface 1114 of the susceptor 2110;
(9) I represents the height of the inlet 1101;
(10) J represents the distance between the surface 1112 of the showerhead component 1110 and the outlet 1140;
(11) L represents the distance between the susceptor axis 1128 and one or more outer edges of the one or more substrate holders 2130 respectively;
(12) M represents the distance between the susceptor axis 1128 and one or more inner edges of the one or more substrate holders 2130 respectively;
(14) N represents the distance between the susceptor axis 1128 and one or more inner edges of the one or more heating devices 1124 respectively; and
(15) O represents the distance between the susceptor axis 1128 and one or more outer edges of the one or more heating devices 1124 respectively.

For example, L minus M is the diameter of the one or more substrate holders 2130. In another example, the vertical size of the reaction chamber 1160 (e.g., represented by H) is equal to or less than 20 mm, or is equal to or less than 15 mm. In yet another example, the vertical size of the inlet 1101 (e.g., represented by I) is less than the vertical distance between the surface 1112 of the showerhead component 1110 and the surface 1114 of the susceptor 2110 (e.g., represented by H). In yet another example, some magnitudes of these dimensions are shown in Table 2 below.

TABLE 2

| | Dimension Magnitude |
|---|---|
| Dimension Symbol | (unit: mm) |
| A | 105 |
| B | 120 |
| C | 150 |
| D | 165 |
| E | 100 |
| F | 330 |
| G | 415 |
| H | 10 |
| I | 5 |
| J | 150 |
| L | 310 |
| M | 145 |
| N | 96 |
| O | 320 |

In one embodiment, the one or more substrate holders 2130 are located on the susceptor 2110. In another embodiment, the one or more heating devices 1124 are located under the one or more substrate holders 2130 respectively. For example, the one or more heating devices 1124 extend toward the center of the reaction chamber 1160 beyond the one or more substrate holders 2130 respectively. In another example, the one or more heating devices 1124 preheat the one or more gases from the inlets 1101, 1102, 1103, and/or 1104 before the one or more gases reach the one or more substrate holders 2130. In yet another example, the one or more gases from the inlets 1101, 1102, 1103, and/or 1104 are preheated by one or more heating devices other than the one or more heating devices 1124, before the one or more gases reach the one or more substrate holders 2130.

As discussed above and further emphasized here, FIGS. 3(A) and (B) are merely examples, which should not unduly limit the scope of the claims. One of ordinary skill in the art would recognize many variations, alternatives, and modifications. For example, the inlet 1102 is replaced by a plurality of inlets, and/or the inlet 1104 is replaced by another plurality of inlets. In another example, the inlet 1102 is formed within the central component 1150 and configured to provide one or more gases in a direction that is substantially parallel to the surface 1112 of the showerhead component 1110.

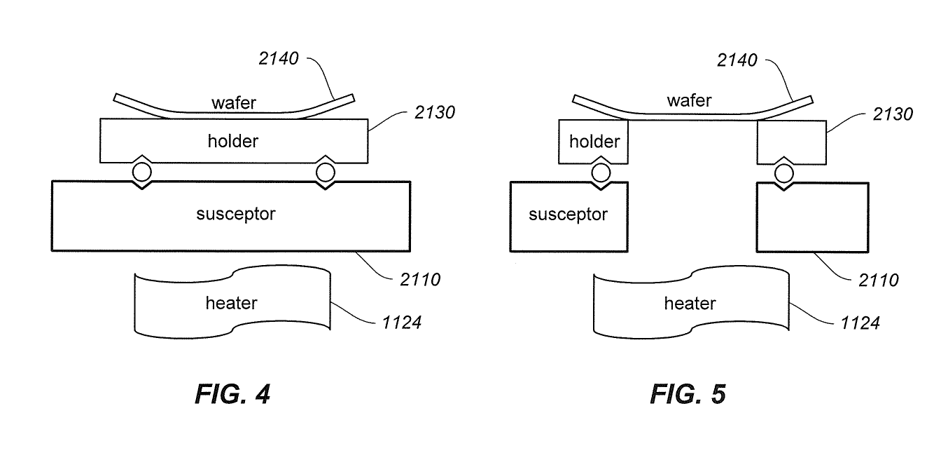

FIG. 4 is a simplified diagram showing indirect heating of a substrate 2140 by a heating device 1124 as part of the reaction system 1100 according to one embodiment. As shown, the substrate 2140 is heated indirectly by the corresponding heating device 1124 through at least the susceptor 2110 and the respective substrate holder 2130. For example, the susceptor 2110 and the substrate holder 2130 can each cause a significant temperature drop ranging from 100° C. to 200° C. In another example, to heat the substrate 2140 up to about 1200° C., the temperature of the heating device 1124 needs to reach about 1500° C. In one embodiment, such high temperature requires high-temperature-resistance materials be used for making the heating device 1124 and the components surrounding the heating device, such as certain components that enable the rotation of the substrate 2140 around the susceptor axis 1128 and/or around the holder axis 1126.

In another embodiment, if the temperature of the substrate holder 2130 is equal to or higher than 900° C., the substrate 2140 is heated primarily by thermal radiation from the substrate holder 2130; thus the heating received by the substrate 2140 is inversely proportional to the square of the distance between the substrate holder 2130 and the substrate 2140 approximately. As shown in FIG. 4, for example, the substrate 2140 has a bow, causing different parts of the substrate 2140 have different distances from the substrate holder 2130. These distance variations are significant because the substrate 2140 overall is close to the substrate holder 2130; hence the temperature non-uniformity caused by the bowing of the substrate 2140 is also significant according to certain embodiments.

FIG. 5 is a simplified diagram showing direct heating of a substrate 2140 by a heating device 1124 as part of the reaction system 1100 according to another embodiment. This diagram is merely an example, which should not unduly limit the scope of the claims. One of ordinary skill in the art would recognize many variations, alternatives, and modifications.

As shown in FIG. 5, the substrate 2140 is heated directly by the corresponding heating device 1124 without through the susceptor 2110 and the respective substrate holder 2130 (e.g., being heated directly by the corresponding heating device 1124 through the hollow parts of the susceptor 2110 and the respective substrate holder 2130).

For example, such direct heating is achieved primarily by thermal radiation from the heating device 1124; thus the heating received by the substrate 2140 is inversely proportional to the square of the distance between the heating device 1124 and the substrate 2140 approximately. In another example, the substrate 2140 has a bow, causing different parts of the substrate 2140 have different distances from the heating device 1124. These distance variations are insignificant because the substrate 2140 overall is far from the heating device 1124; hence the temperature non-uniformity caused by the bowing of the substrate 2140 is insignificant according to some embodiments. In yet another example, the substrate holder 2130 is located directly or indirectly on the susceptor 2110 and configured to support at least one substrate 2140.

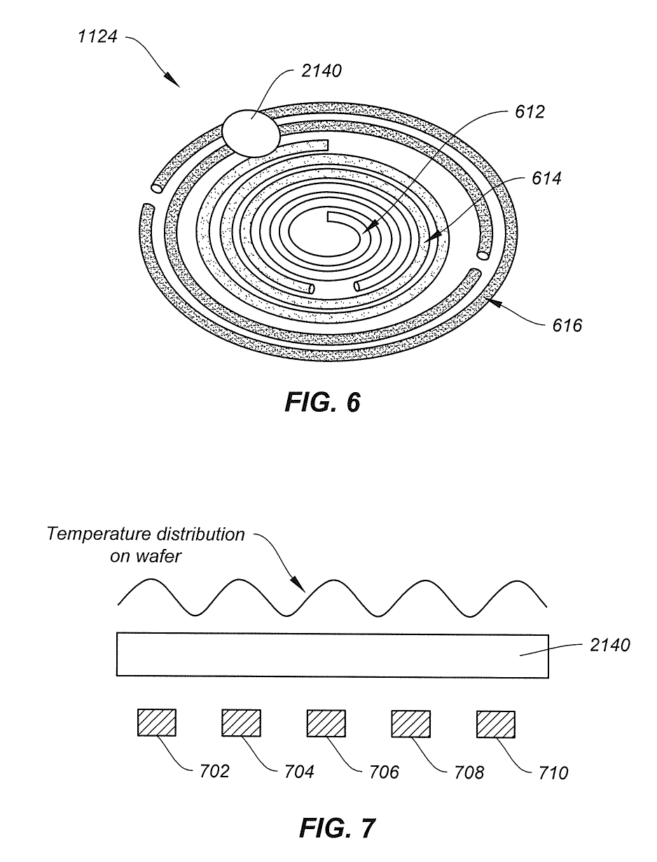

FIG. 6 is a simplified diagram showing the heating device 1124 used for direct heating of the substrate 2140 as shown in FIG. 5 according to one embodiment. The heater 1124 includes one or more heating resistors 612, one or more heating resistors 614, and one or more heating resistors 616. For example, the temperature of the heating resistors 612, the temperature of the heating resistors 614, and the temperature of the heating resistors 616 can be adjusted separately.

FIG. 7 is a simplified diagram showing temperature distribution on the substrate 2140 that is directly heated by the heating device 1124 as shown in FIG. 6 according to one embodiment. For example, the heating device 1124 includes heating resistors 702, 704, 706, 708, and 710, which are selected from the one or more heating resistors 612, the one or more heating resistors 614, and/or the one or more heating resistors 616. In another example, the temperatures of the parts of the substrate 2140 that are directly above the heating resistors 702, 704, 706, 708, and 710 are higher than the temperatures of the parts of the substrate 2140 that are directly above the gaps between the heating resistors 702, 704, 706, 708, and 710.

Referring to FIG. 7, according to another embodiment, the substrate 2140 is replaced by a plurality of substrates 2140 that are located on the same substrate holder 2130. For example, the temperature non-uniformity across the plurality of substrates 2140 can cause inhomogeneity of one or more solid products that are deposited onto the plurality of substrates 2140 by MOCVD. In another example, the temperature non-uniformity can adversely affect uniformity of material quality, material composition, and/or film stress within one substrate and/or across the plurality of substrates.

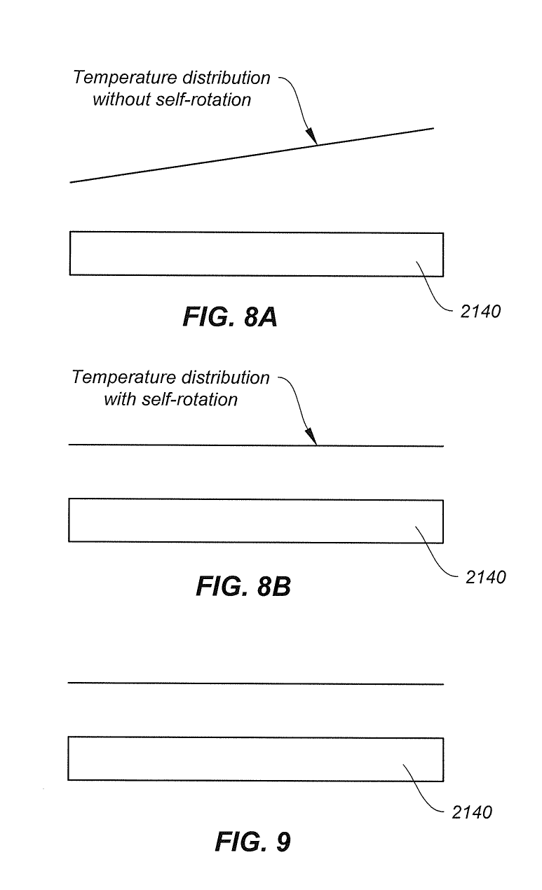

FIGS. 8(A) and (B) are simplified diagrams showing temperature distributions on the substrate 2140 that is directly heated by the heating device 1124 as shown in FIG. 5 according to one embodiment of the present invention. These diagrams are merely examples, which should not unduly limit the scope of the claims. One of ordinary skill in the art would recognize many variations, alternatives, and modifications.

For example, the heating device 1124 is a resistance heating device. In one embodiment, the resistance heating device heats the substrate 2140 directly by at least thermal radiation propagating from the heating device 1124 to the substrate 2140 without through the susceptor component 2110 and the substrate holder 2130. In another example, the heating device 1124 is a radio-frequency (RF) heating device. In one embodiment, the radio-frequency (RF) heating device heats the substrate 2140 directly by at least electromagnetic radiation propagating from the heating device 1124 to the substrate 2140 without through the susceptor component 2110 and the substrate holder 2130.

As shown in FIG. 8(A), without rotation of the substrate 2140 around the corresponding holder axis 1126, the temperature on the substrate 2140 changes linearly along the radial direction from the susceptor axis 1128, even though the substrate 2140 rotates around the susceptor axis 1128. For example, the temperature of the substrate 2140 increases linearly or substantially linearly with increasing distance within a certain distance range from the susceptor axis 1128. In another example, the distance range is equal to or larger than the diameter of the substrate 2140 and/or the diameter of the substrate holder 2130.

As shown in FIG. 8(B), with rotation of the substrate 2140 around the corresponding holder axis 1126 and around the susceptor axis 1128, the temperature on the substrate 2140 remains constant or substantially constant along the radial direction from the susceptor axis 1128.

As discussed above and further emphasized here, FIGS. 8(A) and (B) are merely examples, which should not unduly limit the scope of the claims. One of ordinary skill in the art would recognize many variations, alternatives, and modifications. For example, the substrate 2140 is replaced by a plurality of substrates 2140 that are located on the same substrate holder 2130. In one embodiment, as shown in FIG. 8(A), without rotation of the plurality of substrates 2140 around the corresponding holder axis 1126, the temperature across the plurality of the substrates 2140 changes linearly along the radial direction from the susceptor axis 1128. In another embodiment, as shown in FIG. 8(B), with rotation of the plurality of substrates 2140 around the corresponding holder axis 1126, the temperature across the plurality of the substrates 2140 remains constant along the radial direction from the susceptor axis 1128.

FIG. 9 is a simplified diagram showing temperature distribution on the substrate 2140 that is directly heated by the heating device 1124 as shown in FIG. 5 according to another embodiment of the present invention. This diagram is merely an example, which should not unduly limit the scope of the claims. One of ordinary skill in the art would recognize many variations, alternatives, and modifications.

For example, the heating device 1124 is a resistance heating device. In one embodiment, the resistance heating device heats the substrate 2140 directly by at least thermal radiation propagating from the heating device 1124 to the substrate 2140 without through the susceptor component 2110 and the substrate holder 2130. In another example, the heating device 1124 is a radio-frequency (RF) heating device. In one embodiment, the radio-frequency (RF) heating device heats the substrate 2140 directly by at least electromagnetic radiation propagating from the heating device 1124 to the substrate 2140 without through the susceptor component 2110 and the substrate holder 2130.

As shown in FIG. 9, the temperature on the substrate 2140 remains constant or substantially constant along the radial direction from the susceptor axis 1128, regardless of whether the substrate 2140 rotates around the corresponding holder axis 1126, so long as the substrate 2140 rotates around the susceptor axis 1128.

As discussed above and further emphasized here, FIG. 9 is merely an example, which should not unduly limit the scope of the claims. One of ordinary skill in the art would recognize many variations, alternatives, and modifications. For example, the substrate 2140 is replaced by a plurality of substrates 2140 that are located on the same substrate holder 2130. In another example, the temperature across the plurality of substrates 2140 remains constant or substantially constant along the radial direction from the susceptor axis 1128, regardless of whether the plurality of substrates 2140 rotates around the corresponding holder axis 1126, so long as the plurality of substrates 2140 rotates around the susceptor axis 1128.

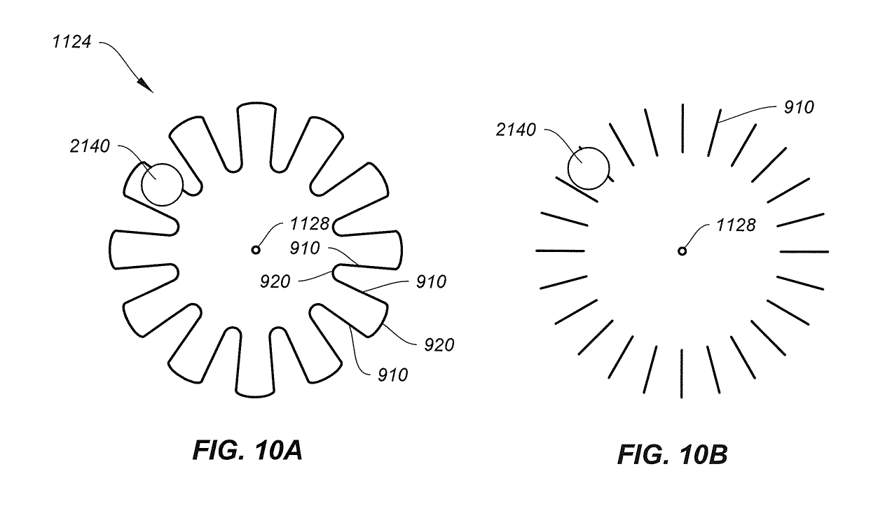

FIGS. 10(A) and (B) are simplified diagrams showing a resistance heating device as the heating device 1124 for directly heating the substrate 2140 as shown in FIG. 5 according to another embodiment of the present invention. These diagrams are merely examples, which should not unduly limit the scope of the claims. One of ordinary skill in the art would recognize many variations, alternatives, and modifications.

As shown in FIG. 10(A), the heating device 1124 includes one or more heating resistors 910 and one or more heating resistors 920. For example, the heating device 1124 heats the substrate 2140 directly by at least thermal radiation propagating from the heating device 1124 to the substrate 2140 without through the susceptor component 2110 and the substrate holder 2130.

In another example, the one or more heating resistors 910 include one or more straight-line resistors that are arranged along one or more radial directions from the susceptor axis 1128 as shown in FIG. 10(B). In one embodiment, the one or more straight-line resistors are located symmetrically with respect to the susceptor axis 1128. In another embodiment, the one or more straight-line resistors each have a length along the corresponding radial direction from the susceptor axis 1128, and the length is equal to or larger than the diameter of the substrate 2140 and/or the diameter of the substrate holder 2130. In yet another example, the one or more heating resistors 920 are used to link the one or more heating resistors 910.

In one embodiment, using the heating device 1124 as shown in FIGS. 10(A) and (B), the temperature on the substrate 2140 changes linearly or substantially linearly along the radial direction from the susceptor axis 1128 as shown in FIG. 8(A), if the substrate 2140 does not rotate around the corresponding holder axis 1126 even though the substrate 2140 rotates around the susceptor axis 1128. In another embodiment, using the heating device 1124 as shown in FIGS. 10(A) and (B), the temperature on the substrate 2140 remains constant or substantially constant along the radial direction from the susceptor axis 1128 as shown in FIG. 8(B), if the substrate 2140 rotates around the corresponding holder axis 1126 and around the susceptor axis 1128. In yet another embodiment, using the heating device 1124 as shown in FIGS. 10(A) and (B), the temperature on the substrate 2140 remains constant or substantially constant along the radial direction from the susceptor axis 1128 as shown in FIG. 9, regardless of whether the substrate 2140 rotates around the corresponding holder axis 1126, so long as the substrate 2140 rotates around the susceptor axis 1128.

As discussed above and further emphasized here, FIGS. 10(A) and (B) are merely examples, which should not unduly limit the scope of the claims. One of ordinary skill in the art would recognize many variations, alternatives, and modifications. For example, the substrate 2140 is replaced by a plurality of substrates 2140 that are located on the same substrate holder 2130. In one embodiment, using the heating device 1124 as shown in FIGS. 10(A) and (B), the temperature on the plurality of substrates 2140 changes linearly along the radial direction from the susceptor axis 1128 as shown in FIG. 8(A), if the plurality of substrates 2140 does not rotate around the corresponding holder axis 1126 even though the plurality of substrates 2140 rotates around the susceptor axis 1128. In another embodiment, using the heating device 1124 as shown in FIGS. 10(A) and (B), the temperature on the plurality of substrates 2140 remains constant along the radial direction from the susceptor axis 1128 as shown in FIG. 8(B), if the plurality of substrates 2140 rotates around the corresponding holder axis 1126 and around the susceptor axis 1128. In yet another embodiment, using the heating device 1124 as shown in FIGS. 10(A) and (B), the temperature across the plurality of substrates 2140 remains constant or substantially constant along the radial direction from the susceptor axis 1128 as shown in FIG. 9, regardless of whether the plurality of substrates 2140 rotates around the corresponding holder axis 1126, so long as the plurality of substrates 2140 rotates around the susceptor axis 1128.

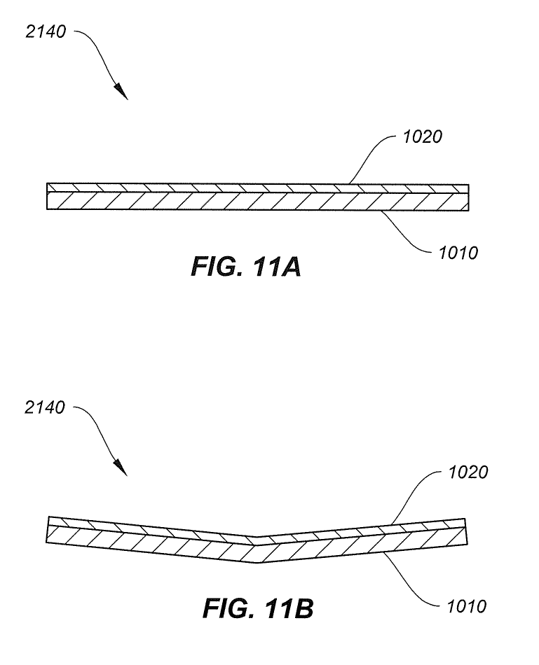

Referring to FIGS. 8(A), 8(B), and 9, in one embodiment, the substrate 2140 is covered by one or more heat-conductive materials at the bottom surface of the substrate 2140 that directly faces the heating device 1124. For example, the one or more heat-conductive materials have heat conductivity that is substantially higher than (e.g., by at least three times) the substrate 2140. In another embodiment, the heating device 1124 is a radio-frequency (RF) heating device. For example, the radio-frequency (RF) heating device includes one or more planar coils. In another example, the substrate 2140 that is directly heated by the radio-frequency (RF) heating device is shown in FIGS. 11(A) and/or (B).

FIGS. 11(A) and (B) are simplified diagrams showing the substrate 2140 that can be directly heated by the radio-frequency (RF) heating device as the heating device 1124 as shown in FIG. 5 according to certain embodiments of the present invention. These diagrams are merely examples, which should not unduly limit the scope of the claims. One of ordinary skill in the art would recognize many variations, alternatives, and modifications. For example, the substrate 2140 as shown in FIG. 11(B) is bended more significantly (e.g., at a higher temperature) than the substrate 2140 as shown in FIG. 11(A). In another example, the substrate 2140 includes a layer 1010 and a layer 1020, which is located on the layer 1010.

In one embodiment, the layer 1020 is optically transparent. For example, the layer 1020 is comprised of transparent sapphire. In another embodiment, the layer 1010 is heat absorbing. For example, the layer 1010 is comprised of one or more resistive materials that can effectively absorb energy from radio-frequency electromagnetic waves. In another example, the layer 1010 is comprised of graphite, silicon, carbide, silicon carbide, silicone-carbide-coated graphite, and/or diamond-like carbon.

In yet another embodiment, the substrate 2140 as shown in FIGS. 11(A) and (B) is made by painting, coating, and/or other thick-film deposition processes. For example, the substrate 2140 is suitable for use with the radio-frequency (RF) heating device. In another example, the substrate 2140 improves efficiency of directing heating, and/or uniformity of temperature of the layer 1020. In yet another embodiment, after the one or more solid products (e.g., one or more thin films) are deposited onto the surface of the layer 1020 by the reaction system 1100, the layer 1010 is peeled off the layer 1020.

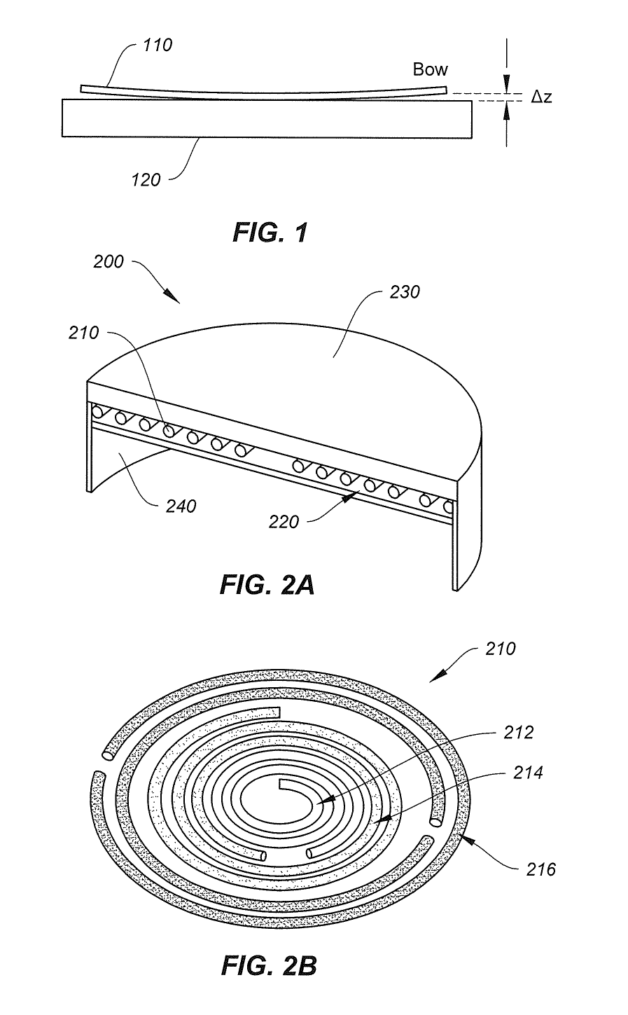

Referring to FIGS. 1, 2(A) and 2(B), as discussed above, when the substrate 110 is heated through the substrate holder 120, the bowing of the substrate 110 can lead to temperature non-uniformity, causing inhomogeneity of one or more solid products that are deposited onto the substrate by MOCVD.

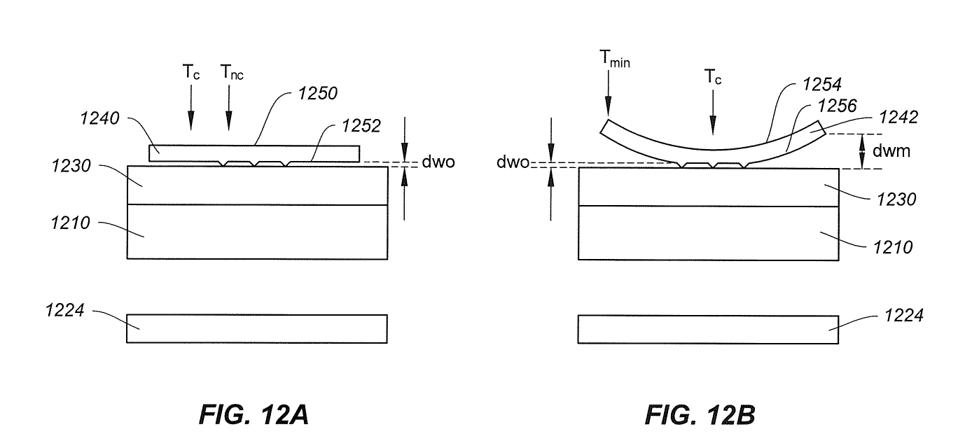

FIGS. 12 (A) and (B) are simplified diagrams showing effects of bowing of a substrate on substrate temperature according to certain embodiments. For example, a substrate 1240 without bowing is heated by a heating device 1224 through a susceptor 1210 and a substrate holder 1230. In another example, a substrate 1242 with bowing is heated by the heating device 1224 through the susceptor 1210 and the substrate holder 1230.

As shown in FIG. 12(A), the substrate 1240 has a top surface 1250 and a bottom surface 1252, without bowing according to one embodiment. For example, the bottom surface 1252 has a plurality of protrusions. In another example, the plurality of protrusions form a plurality of contact points with the substrate holder 1230. In yet another example, the rest of the bottom surface is not in direct contact with the substrate holder 1230, and is certain distance (i.e., d_{w0}) away from the substrate holder 1230. In yet another example, d_{w0} represents the largest height of the plurality of protrusions measured from the rest of the bottom surface 1252.

According to another embodiment, the temperature non-uniformity (i.e., ΔT₀) of the substrate 1240 is determined as follows:

ΔT₀=T_{c}−T_{nc} (Equation 1)

where Tₑ represents the substrate temperature corresponding to one or more contact points, and T_{nc} represents the substrate temperature not corresponding to any contact point.

As shown in FIG. 12(B), the substrate 1242 has a top surface 1254 and a bottom surface 1256, with bowing according to one embodiment. For example, the bottom surface 1256 has a plurality of protrusions. In another example, the plurality of protrusions form a plurality of contact points with the substrate holder 1230. In yet another example, the rest of the bottom surface 1256 is not in direct contact with the substrate holder 1230, and is certain distance (i.e., d_{w}) away from the substrate holder 1230, where d_{w0}≦d_{w}≦d_{wm}. In yet another example, d_{w0} represents the largest heightᵥₙ, of the plurality of protrusions measured from the rest of the bottom surface 1256, and d_{wm} represents the distance between the substrate holder 1230 and the highest point of the bottom surface 1256. In yet another example, d_{wm}−d_{w0} represents height of the bow (e.g., ΔZ).

According to another embodiment, the temperature non-uniformity (i.e., ΔT_{b}) of the substrate 1242 is determined as follows:

ΔT_{b}=T_{c}−Tₘᵢₙ (Equation 2)

where T_{c} represents the substrate temperature corresponding to one or more contact points, and Tₘᵢₙ represents the substrate temperature corresponding to one or more locations on the bottom surface 1256 that are farthest away from the substrate holder 1230.

According to yet another embodiment, the temperature non-uniformity (i.e., ΔT_{b}) of the substrate 1242 is compared with the temperature non-uniformity (i.e., ΔT₀) of the substrate 1240 as follows:

$$Δ {T}_{b} - Δ {T}_{0} = ( {T}_{c} - {T}_{min} ) - ( {T}_{c} - {T}_{nc} ) = {T}_{nc} - {T}_{min} ∝ \vert \frac{1}{{d}_{w 0}} - \frac{1}{{d}_{wm}} \vert \qquad ( Equation 3 )$$

Hence, ΔT_{b}−ΔT₀ can vary significantly with

$$\vert \frac{1}{{d}_{w 0}} - \frac{1}{{d}_{wm}} \vert$$

according to yet another embodiment.

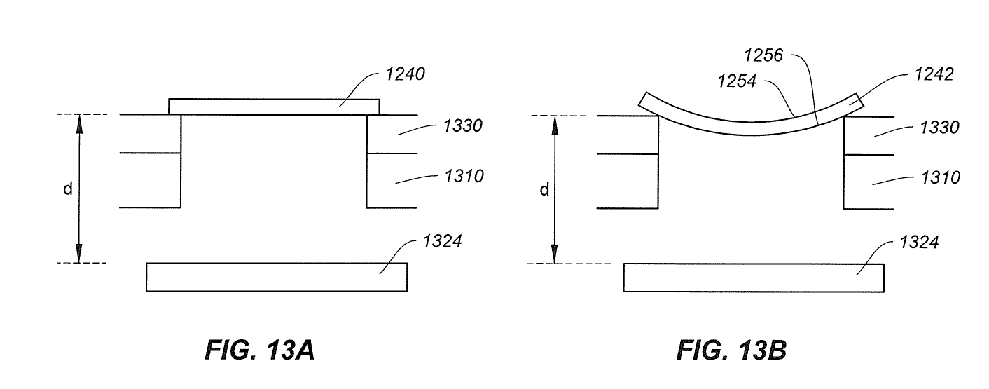

FIGS. 13 (A) and (B) are simplified diagrams showing effects of bowing of a substrate on substrate temperature according to some embodiments. These diagrams are merely examples, which should not unduly limit the scope of the claims. One of ordinary skill in the art would recognize many variations, alternatives, and modifications.

For example, the substrate 1240 without bowing is heated by a heating device 1324 through the hollow parts of a susceptor 1310 and a substrate holder 1330. In another example, the substrate 1242 with bowing is heated by the heating device 1324 through the hollow parts of the susceptor 1310 and the substrate holder 1330. In yet another example, the susceptor 1310 is the same as the susceptor 2110, the substrate holder 1330 is the same as the substrate holder 2130, and the heating device 1324 is the same as the heating device 1124, as shown in FIG. 5. In yet another example, the substrate 1242 is the same as the substrate 2140 as shown in FIG. 5.

In one embodiment, the temperature non-uniformity (i.e., ΔT_{b}) of the substrate 1242 in FIG. 13(B) is compared with the temperature non-uniformity (i.e., ΔT₀) of the substrate 1240 in FIG. 13(A) as follows:

$$Δ {T}_{b} - Δ {T}_{0} = ( {T}_{c} - {T}_{min} ) - ( {T}_{c} - {T}_{nc} ) ∝ \vert \frac{1}{d + {d}_{w 0}} - \frac{1}{d + {d}_{wm}} \vert \qquad ( Equation 4 )$$

Hence, if d>>d_{w0} and d>>d_{wm},

ΔT_{b}−ΔT₀≈0 (Equation 5)

as shown in FIG. 5 according to certain embodiments. In one embodiment, if d>>d_{wm}−d_{w0}, Equation 5 is achieved. For example, d_{wm}−d_{w0} represents height of the bow (e.g., ΔZ). In another example, if d is at least 20 times, 50 times, or 100 times as large as the height of the bow, Equation 5 is achieved.

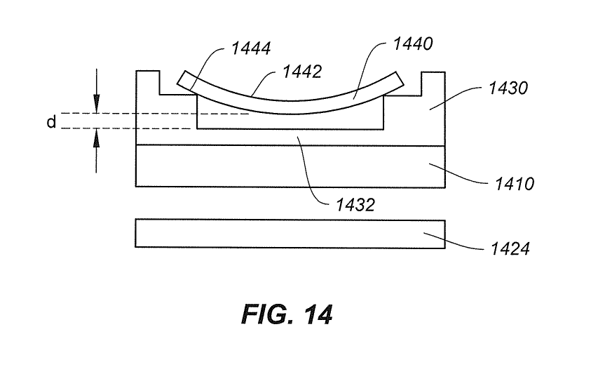

FIG. 14 is a simplified diagram showing distant heating of a substrate 1440 by a heating device 1424 through a susceptor 1410 and a corresponding substrate holder 1430 as part of the reaction system 1100 according to yet another embodiment. This diagram is merely an example, which should not unduly limit the scope of the claims. One of ordinary skill in the art would recognize many variations, alternatives, and modifications. For example, the susceptor 1410 serves as the susceptor 2110, the substrate holder 1430 serves as the substrate holder 2130, and the heating device 1424 serves as the heating device 1124. In another example, the substrate 1440 is the same as the substrate 1242.

In one embodiment, the substrate 1440 has a top surface 1442 and a bottom surface 1444 with bowing. In another embodiment, the substrate holder 1430 includes a lower portion 1432 that is certain distance (e.g., d) away from the bottom surface 1444 of the substrate 1440. In yet another embodiment, the substrate 1440 is heated by the heating device 1424 through the susceptor 1410 and the lower portion 1432 of the respective substrate holder 1430. For example, the lower portion 1432 is heated by the heating device 1424, and serves as a heating device to heat the substrate 1440. In yet another embodiment, the substrate holder 1430 is located directly or indirectly on the susceptor 1410 and configured to support at least one substrate 1440.

As shown in FIG. 14, the substrate 1440 has a bow, causing different parts of the substrate 1440 to have different distances from the lower portion 1432 of the substrate holder 1430. According to one embodiment, these distance variations are insignificant because the substrate 1440 overall is far from the lower portion 1432 of the substrate holder 1430; hence the temperature non-uniformity caused by the bowing of the substrate 1440 is insignificant. According to another embodiment, based on Equations 4,

if d>>ΔZ,

ΔT_{b}−ΔT₀≈0 (Equation 6)

where ΔZ represents height of the bow. For example, d is at least 20 times, 50 times, or 100 times as large as ΔZ.

According to another embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates directly without through the susceptor component and the substrate holder. The heating device is further configured to provide a first temperature on the one or more substrates only if the one or more substrates rotate around at least the susceptor axis, and the first temperature is constant along the radial direction from the susceptor axis. For example, the system is implemented according to at least FIG. 5, FIG. 8(A), and/or FIG. 8(B).

According to yet another embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates directly without through the susceptor component and the substrate holder. The heating device is further configured to provide a first temperature on the one or more substrates only if the one or more substrates rotate around at least the susceptor axis, and the first temperature is constant along a first radial direction from the susceptor axis. The heating device includes a first plurality of heating resistors and a second plurality of heating resistors. Each of the first plurality of heating resistors is located along a second radial direction from the susceptor axis, and each of the second plurality of heating resistors is conductively connected to at least two heating resistors selected from the first plurality of heating resistors. For example, the system is implemented according to at least FIG. 5, FIG. 10(A), and/or FIG. 10(B).

According to yet another embodiment, a system for forming one or more layers of one or more materials on one or more substrates includes a susceptor component configured to rotate around a susceptor axis, and at least one substrate holder located directly or indirectly on the susceptor component and configured to support the one or more substrates. The substrate holder is further configured to cause the one or more substrates to rotate around at least the susceptor axis. Additionally, the system includes at least one heating device configured to heat the one or more substrates. Each of the one or more substrates includes a substrate surface facing the heating device and associated with a bow height (e.g., ΔZ), and the heating device is located away from the substrate surface by a distance. For each of the one or more substrates, the distance is at least twenty times as large as the bow height. For example, the system is implemented according to at least FIG. 5, FIG. 13(A), FIG. 13(B), and/or FIG. 14.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A system for forming one or more layers of one or more materials on one or more substrates, the system comprising:
a susceptor component configured to rotate around a susceptor axis;
at least one substrate holder located directly or indirectly on the susceptor component and configured to support the one or more substrates, the substrate holder being further configured to cause the one or more substrates to rotate around at least the susceptor axis; and
at least one heating device configured to heat the one or more substrates directly without through the susceptor component and the substrate holder;
wherein the heating device is further configured to provide a first temperature on the one or more substrates only if the one or more substrates rotate around at least the susceptor axis, the first temperature being constant along the radial direction from the susceptor axis.

2. The system of claim 1 wherein the heating device is further configured to provide the first temperature on the one or more substrates if the one or more substrates rotate around the susceptor axis, regardless of whether the one or more substrates also rotate around a corresponding holder axis.

3. The system of claim 1 wherein the substrate holder is further configured to cause the one or more substrates to rotate around a corresponding holder axis, the corresponding holder axis being different from the susceptor axis.

4. The system of claim 3 wherein the heating device is further configured to:
provide a second temperature on the one or more substrates if the one or more substrates rotate around the susceptor axis but not around the corresponding holder axis, the second temperature changing linearly along a radial direction from the susceptor axis; and
provide the first temperature on the one or more substrates if the one or more substrates rotate around the susceptor axis and also rotate around the corresponding holder axis.

5. The system of claim 4 wherein the second temperature changes linearly within a first dimension along the radial direction, the first dimension being equal to or larger than a second dimension along the radial direction for the substrate holder.

6. The system of claim 1 wherein the heating device is further configured to heat the one or more substrates directly through one or more hollow parts of the susceptor component and the substrate holder.

7. The system of claim 1 wherein the heating device includes one or more heating resistors.

8. The system of claim 1 wherein the heating device includes one or more coils.

9. The system of claim 1 wherein the heating device is further configured to heat the one or more substrates directly by at least thermal radiation propagating from the heating device to the one or more substrates without through the susceptor component and the substrate holder.

10. The system of claim 1 wherein the heating device is further configured to heat the one or more substrates directly by at least electromagnetic radiation propagating from the heating device to the one or more substrates without through the susceptor component and the substrate holder.

11. The system of claim 10 wherein:
each of the one or more substrates includes a first layer and a second layer;
the first layer includes one or more optically-transparent materials; and
the second layer includes one or more resistive materials absorbing energy from the electromagnetic radiation.

12. The system of claim 11 wherein the one or more optically-transparent materials include transparent sapphire.

13. The system of claim 11 wherein the one or more resistive materials include at least one selected from a group consisting of graphite, silicon, carbide, silicon carbide, silicone-carbide-coated graphite, and diamond-like carbon.

14. The system of claim 1 wherein each of the one or more substrates is covered by a heat-conductive layer facing the heating device.

15. The system of claim 14 wherein the heat-conductive layer is associated with a first heat conductivity that is at least three times of a second heat conductivity of the each of the one or more substrates.

16. A system for forming one or more layers of one or more materials on one or more substrates, the system comprising:
a susceptor component configured to rotate around a susceptor axis;
at least one substrate holder located directly or indirectly on the susceptor component and configured to support the one or more substrates, the substrate holder being further configured to cause the one or more substrates to rotate around at least the susceptor axis; and
at least one heating device configured to heat the one or more substrates directly without through the susceptor component and the substrate holder;
wherein:
the heating device is further configured to provide a first temperature on the one or more substrates only if the one or more substrates rotate around at least the susceptor axis, the first temperature being constant along a first radial direction from the susceptor axis; and
the heating device includes a first plurality of heating resistors and a second plurality of heating resistors, each of the first plurality of heating resistors being located along a second radial direction from the susceptor axis, each of the second plurality of heating resistors being conductively connected to at least two heating resistors selected from the first plurality of heating resistors.

17. The system of claim 16 wherein the heating device is further configured to provide the first temperature on the one or more substrates if the one or more substrates rotate around the susceptor axis, regardless of whether the one or more substrates rotate around a corresponding holder axis.

18. The system of claim 16 wherein the substrate holder is further configured to cause the one or more substrates to rotate around a corresponding holder axis, the corresponding holder axis being different from the susceptor axis.

19. The system of claim 18 wherein the heating device is further configured to:
provide a second temperature on the one or more substrates if the one or more substrates rotate around the susceptor axis but not around the corresponding holder axis, the second temperature changing linearly along a radial direction from the susceptor axis; and
provide the first temperature on the one or more substrates if the one or more substrates rotate around the susceptor axis and also rotate around the corresponding holder axis.

20. The system of claim 16 wherein the first plurality of heating resistors is located symmetrically with respect to the susceptor axis.

21. The system of claim 16 wherein, for at least one of the first plurality of heating resistors, a first dimension along the second radial direction is equal to or larger than a second dimension along the second radial direction for the substrate holder.

22. The system of claim 16 wherein, for at least one of the first plurality of heating resistors, the second radial direction is the same as the first radial direction.

23. The system of claim 16 wherein the heating device is further configured to heat the one or more substrates directly through one or more hollow parts of the susceptor component and the substrate holder.

24. The system of claim 16 wherein the heating device is further configured to heat the one or more substrates directly by at least thermal radiation propagating from the heating device to the one or more substrates without through the susceptor component and the substrate holder.

25. The system of claim 16 wherein each of the one or more substrates is covered by a heat-conductive layer facing the heating device.

26. The system of claim 25 wherein the heat-conductive layer is associated with a first heat conductivity that is at least three times of a second heat conductivity of the each of the one or more substrates.

27. A system for forming one or more layers of one or more materials on one or more substrates, the system comprising:
a susceptor component configured to rotate around a susceptor axis;
at least one substrate holder located directly or indirectly on the susceptor component and configured to support the one or more substrates, the substrate holder being further configured to cause the one or more substrates to rotate around at least the susceptor axis; and
at least one heating device configured to heat the one or more substrates;
wherein:
each of the one or more substrates includes a substrate surface facing the heating device and associated with a bow height; and
the heating device is located away from the substrate surface by a distance;
wherein for each of the one or more substrates, the distance is at least twenty times as large as the bow height.

28. The system of claim 27 wherein for each of the one or more substrates, the distance is at least fifty times as large as the bow height.

29. The system of claim 27 wherein for each of the one or more substrates, the distance is at least one hundred times as large as the bow height.

30. The system of claim 27 wherein the heating device includes a part of the substrate holder, the part of the substrate holder being located away from the substrate surface by the distance.

31. The system of claim 27 wherein the heating device is further configured to provide a first temperature on the one or more substrates only if the one or more substrates rotate around at least the susceptor axis, the first temperature being constant along the radial direction from the susceptor axis.
